(19) United States
(12) Patent Application Publication
(10) Pub. No.: US 2022/0166075 A1
(43) Pub. Date: May 26, 2022

(54) Method for Enhancing a Battery Module Model of a Battery Module Type

(71) Applicant: Siemens Aktiengesellschaft, Muenchen (DE)

(72) Inventors: Gergely György BALAZS, Budapest (HU); Kristian FENECH, Budapest (HU)

(21) Appl. No.: 17/602,396

(22) PCT Filed: Apr. 2, 2020
(86) PCT No.: PCT/EP2020/059456

§ 371 Date: Oct. 8, 2021

(30) Foreign Application Priority Data
Apr. 10, 2019 (EP) 19168327

(51) Int. Cl. H01M 10/42; H01M 10/48; G01R 31/367; G01R 31/392

(52) U.S. Cl. CPC H01M 10/4285; H01M 10/482; H01M 2010/4278; G01R 31/367; G01R 31/392; H01M 10/425

(57) ABSTRACT

A method for enhancing a battery module model of a battery module type includes a) exposing a battery module to a first environment and measuring an initial battery parameter, b) training the battery module model of the battery module type with the initial battery parameter based on machine learning techniques, c) operating the battery module at a second environment with changing environmental conditions and capturing an operating battery parameter, d) training the battery module model with the operating battery parameter, e) calculating an end-of life (EOL) parameter (40) relating to an EOL prediction of the battery module, where if the EOL parameter exceeds a predetermined threshold value, then the method continues with step f), other a return to step c) occurs, f) exposing the battery module to a third environment and measuring a final battery parameter, and g) training the battery module model with the final battery parameter.

### CROSS-REFERENCE TO RELATED APPLICATIONS

This is a U.S. national stage of application No. PCT/EP2020/059456 filed 2 Apr. 2020. Priority is claimed on European Application No. 19168327.5 filed 10 Apr. 2019, the content of which is incorporated herein by reference in its entirety.

### BACKGROUND OF THE INVENTION

### 1. Field of the Invention

The invention relates to a device, system and a method for enhancing a battery module model of a battery module type.

### 2. Description of the Related Art

The aging of a Lithium-Ion battery pack is a very important issue, which two factors contribute essentially. The first, calendar aging is due to the progression of time since the manufacturing of the cell or group of cells within a battery pack. The second is aging due to charge-discharge cycles. However, this second aging factor is a highly non-linear process in which many factors such as temperature, charge/discharge rate, and changes in charge/discharge rate play a role.

This lack of information regarding the battery aging can result in incorrect capacity estimations for state of charge algorithms.

In conventional batteries, aging and capacity was estimated by specific offline measurements to assess the remaining battery capacity. Such measurements include Open Circuit Voltage (OCV) measurement to deduce Internal resistance. Additionally, low C-rate charge-discharge measurements can be made to establish remaining capacity.

### SUMMARY OF THE INVENTION

It is an object of the invention to provide an enhanced battery module model of a battery module type to allow the accurate estimation of the effective age of a battery module of the battery module type without interrupting the continuous usage of the module under investigation.

This and other objects and advantages are achieved in accordance with the invention by a method comprising:
a) exposing a battery module of the battery module type including a plurality of battery cells to a first environment and measuring at the first environment at least one initial battery parameter based on at least one-time parameter,
b) setting up and training the battery module model of the battery module type with the at least one initial battery parameter based on the at least one-time parameter and based on machine learning techniques,
c) operating the battery module at a second environment with changing environmental conditions and capturing at least one operating battery parameter,
d) training the battery module model with the at least one operating battery parameter based on the at least one-time parameter,
e) calculating an end-of-life (EOL) parameter relating to an EOL prediction of the battery module,
f) exposing the battery module to a third environment and measuring at the third environment at least one final battery parameter based on the at least one-time parameter, and
g) training the battery module model with the at least one final battery parameter based on the at least one time parameter.

Thus, the estimation on active/in field batteries can be performed without interfering with day-to-day operations.

In other words, the battery module of the battery module type including a plurlity of battery cells is exposed during practicing the method subsequently to:
a first environment and measurements are performed there,
a second environment and measurements are performed there,
a third environment and measurements are performed there,
   whereas these three environments are different from each other.

The first environment can be, for instance, the production environment, where the battery module is manufactured or in a lab. Here, preferably constant environmental conditions apply.

The second environment can be, for instance, the operating environment, where the battery module acts as a power source, e.g., at an aircraft. Here, charge/discharge measurements are performed during the operation of the battery module, e.g., at a car, an aircraft or a mobile computer, delivering as in-field battery reporting the operating parameter for current and the operating parameter for voltage at the operating environment.

Consequently, non-constant environmental conditions can apply to the second environment. Thus, at the second environment the environmental conditions, such as temperature or loads, can change during the duration of the exposure to the second environment.

Preferably, the second environment is applied during operation of the battery module, i.e., while providing power to an electric load. No controlled charge/discharge cycles are applied then and the charge/discharge “mode” of the electric load, e.g., a generator or a motor, connected to the battery module is used.

The third environment can be for instance a final environment, e.g., in the lab, where the module is removed from its operating environment, e.g., before battery recycling. Here, preferably constant environmental conditions apply.

In the prior art, subsequent measurements for building a model are only known at equal conditions, i.e., comparable environments.

In accordance with the invention, the support of different environments during the measuring steps adds flexibility and lowers the costs of gathering the required measurement data.

Each environment can be characterized by individual temperature, air pressure, humidity, electrical load, and/or mechanical load. This is achieved by the remote transmission of in use battery characteristics to a remote server for processing, which eliminates the constraint set by low power processors typically found within local battery management systems.

Further, the method enhances safety by detecting battery packs that may be undergoing enhanced degradation due to manufacturing, environmental or abnormal usage patterns. This is achieved by the aging prediction model that can detect such packs as described.

Moreover, the down-time and costs are minimized due to unrecognized battery packs which have decreased beyond useable life. This is achieved as the battery Information is automatically made available and comparison to a reference pack made during an optimized maintenance schedule can be derived.

Additionally, by predicting aging and capacity on a pre-trained model means the battery pack under observation does not need to be removed for lab tests.

In one further embodiment of the invention, the at least one initial battery parameter and/or the at least one operating battery parameter and/or the at least one final battery parameter is related to a voltage, a current and/or a charge of the battery module or at least one cell of the multiplicity of battery cells.

In another further embodiment of the invention, the measuring step f) is performed by applying at least one controlled discharge on the battery module and/or at least one cell of the multiplicity of battery cells.

In another further embodiment of the invention, after the measuring step f) the at least one final battery parameter is compared with the at least one initial battery parameter based on Bayesian classification, where the classification results are used at the training step g).

It is also an object of the invention to provide a device for predicting the effective age of a battery module including a plurality of battery cells, where the device is configured to receive at least one battery parameter, setup a battery module model based on machine learning techniques using the at least one battery parameter, train the battery module model with the at least one battery parameter set, output an end-of-life prediction parameter of the battery module based on the battery module model, and perform the step after the measuring step f) in accordance with the method of the invention.

It is also an object of the invention to provide a system for predicting the effective age of a battery module, where the system comprises a battery module including a plurality of battery cells and a prediction device in accordance with the device in accordance with the invention.

It should be understood that further parts not shown or illustrated are necessary for the operation of a battery module, e.g., electronic control components or measurement equipment. For the sake of clarity and a better understanding these parts are not illustrated and/or described.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention is described by an embodiment in the accomplished figures in detail, in which:

FIG. 1 is a schematic illustration of a battery module of the battery module type including a plurality of battery cells in accordance with the invention;

FIG. 2 is a schematic illustration of an embodiment of the steps of the method in accordance with the invention;

FIG. 3 is a further schematic illustration of the method of FIG. 1; and

FIG. 4 is a schematic illustration of an embodiment of a device in accordance with the invention.

### DETAILED DESCRIPTION OF THE EXEMPLARY EMBODIMENTS

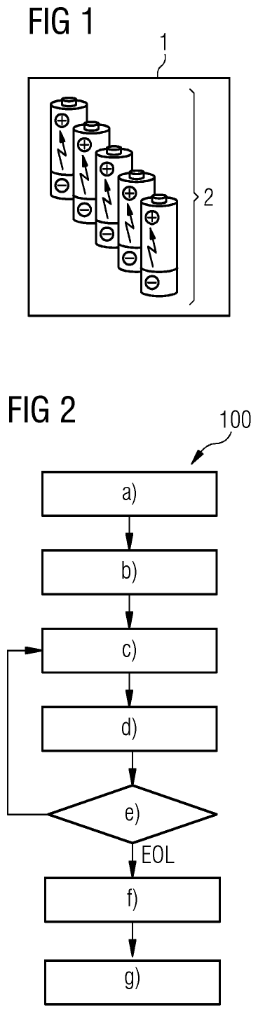

FIG. 1 shows a schematic illustration of a battery module 1 of the battery module type including a plurality of battery cells 2.

FIG. 2 shows the method for enhancing a battery module model of a battery module type, comprising:
a) exposing a battery module 1 of the battery module type including a plurality of battery cells 2 to a first environment 10 and measuring at the first environment 10 at least one initial battery parameter 11, 12, 13 based on at least one time parameter 3,
b) setting up and training the battery module model of the battery module type with the at least one initial battery parameter 11, 12, 13 based on the at least one-time parameter 3 and based on machine learning techniques,
c) operating the battery module 1 at a second environment 20 with changing environmental conditions and capturing at least one operating battery parameter 21, 22,
d) training the battery module model with the at least one operating battery parameter 21, 22 based on the at least one-time parameter 3,
e) calculating an EOL parameter 40 relating to an end-of-life prediction of the battery module 1, where, if the EOL parameter 40 exceeds a predetermined threshold value, then the method continues with step f), otherwise the method returns to step c),
f) exposing the battery module 1 to a third environment 30 and measuring at the third environment 30 at least one final battery parameter 31, 32 based on the at least one-time parameter 3, and
g) training of the battery module model with the at least one final battery parameter 31, 32 based on the at least one-time parameter 3.

Within step a), a set of battery modules can be used for providing initial data for the setup of the battery module model in step b).

The at least one initial battery parameter 11, 12, 13 and the at least one operating battery parameter 21, 22 and the at least one final battery parameter 31, 32 are related to a voltage, a current and a charge of the battery module 1 and at least one cell of the multiplicity of battery cells 2.

The measuring step f) is performed by applying at least one controlled discharge on the battery module 1, i.e., at least one cell of the multiplicity of battery cells 2.

After the measuring step f) the at least one final battery parameter 31, 32 is compared with the at least one initial battery parameter 11, 12, 13 based on a Bayesian classification, where the classification results are used at the training step g).

The first environment 10 and the third environment 30 can be the same, e.g., at a lab. As a result, an aged battery module at end-of-life can provide important data for the battery module model for another battery module of the same battery type during its ongoing operation.

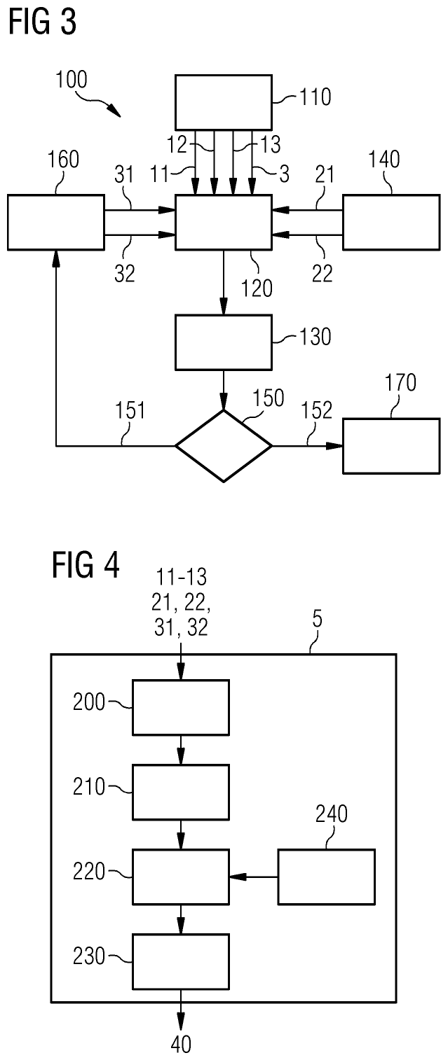

FIG. 3 shows an alternative schematic illustration 100 of the embodiment of the steps of the method in accordance with the invention.

Within step a), controlled charge/discharge measurements 110 are performed, delivering the initial parameters for current 11, the initial parameters for voltage 12 and the initial parameters for charge 13 at the initial environment 10 based on the time parameter 3.

The time parameter 3 can be a reference to all other measurements, i.e., measurements can be normalized to the time parameter 3.

Within step b), the battery module model is setup and trained, i.e., an aging prediction model training 120 is performed, with the initial battery parameters 11, 12, 13 based on the time parameter 3 and based on machine learning techniques.

Within step c), charge/discharge measurements 140 are performed during the operation of the battery module, e.g., at a car, an aircraft or a mobile computer, delivering as in-field battery reporting 140 the operating parameter for current 21 and the operating parameter for voltage 22 at the operating environment 20. Thus, at the second environment, the environmental conditions can change during the duration of the exposure to the second environment.

Subsequently, an aging model prediction 130 is performed, where the end-of-life parameter EOL 40 is calculated and compared 150 to a pre-set value, e.g., 70%, 75% or 80% of the original, initial capacity of the battery module. The pre-set value depends on the application where the battery module is used and can vary over a wide range.

When end-of-life of the battery module is reached in path 151, further controlled charge/discharge measurements 160 are performed in step f), delivering the final parameters for current 31 and the final parameters for voltage 32 at the final environment 30 based on the time parameter 3.

As long as the end-of-life of the battery module in path 152 is not yet reached, the battery operation will continue in path 170. i.e., the “regular” battery operation within its application is continued, and periodically step c) is repeated.

FIG. 4 depicts an embodiment of a device 5 in accordance with the invention, which can also be used in a system. The device 5 for enhancing a battery module model of a battery module type is configured to:
receive 200 at least one battery parameter 11, 12, 13, 21, 22, 31, 32 of a battery module 1 that includes a plurality of battery cells,
setup 210 a battery module model based on machine learning techniques using the at least one battery parameter 11, 12, 13,
train 220 the battery module model with the at least one battery parameter set 11, 12, 13, 21, 22, 31, 32,
output 230 an end-of-life prediction parameter 40 of the battery module 1 based on the battery module model,
perform 240, after the measuring step f), a comparison of the at least one final battery parameter 31, 32 with the at least one initial battery parameter 11, 12, 13 based on Bayesian classification, where the classification results are used at the training step g).

Thus, the device 5 provides an improved battery module model of a battery module 1 and/or its EOL parameter 40.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.- 6. (canceled)

7. A method for enhancing a battery module model of a battery module type, the method comprising:
a) exposing a battery module of the battery module type including a plurality of battery cells to a first environment and measuring at the first environment at least one initial battery parameter based on at least one-time parameter;
b) setting up and training the battery module model of the battery module type with the at least one initial battery parameter based on the at least one-time parameter and based on machine learning techniques;
c) operating the battery module at a second environment with changing environmental conditions and capturing at least one operating battery parameter;
d) training the battery module model with the at least one operating battery parameter based on the at least one-time parameter;
e) calculating an end-of life parameter relating to an EOL prediction of the battery module, if the EOL parameter exceeds a predetermined threshold value then continue with subsequent step f), otherwise return to step c);
f) exposing the battery module to a third environment and measuring at the third environment at least one final battery parameter based on the at least one-time parameter;
g) training the battery module model with the at least one final battery parameter based on the at least one-time parameter.

8. The method according to claim 7, wherein at least one of (i) the at least one initial battery parameter, (ii) the at least one operating battery parameter and (iii) the at least one final battery parameter is related to at least one of (i) a voltage, (ii) a current and (iii) a charge of the battery module or at least one cell of the multiplicity of battery cells.

9. The method according to claim 7, wherein said measuring step f) is performed by applying at least one of (i) at least one controlled discharge on the battery module and (ii) at least one cell of the multiplicity of battery cells.

10. The method according to claim 7, wherein after said measuring step f) the at least one final battery parameter is compared with the at least one initial battery parameter based on a Bayesian classification, said classification results being utilized at the training step g).

11. A device for predicting an effective age of a battery module including a plurality of battery cells, wherein the device is configured to:
receive at least one battery parameter,
setup a battery module model based on machine learning techniques utilizing the at least one battery parameter,
train the battery module model with the at least one battery parameter,
output an end-of-life prediction parameter of the battery module based on the battery module model,
compare at least one final battery parameter with at least one initial battery parameter based on a Bayesian classification, said classification results being utilized during said training.

12. A system for predicting an effective age of a battery module, wherein the system comprises a battery module including a multiplicity of battery cells and the prediction device according to claim 11.
